(19) United States
(12) Patent Application Publication
(10) Pub. No.: US 2015/0380392 A1
(43) Pub. Date: Dec. 31, 2015

(54) PACKAGE WITH MEMORY DIE AND LOGIC DIE INTERCONNECTED IN A FACE-TO-FACE CONFIGURATION

(71) Applicant: Apple Inc., Cupertino, CA (US)

(72) Inventors: Mengzhi Pang, Cupertino, CA (US); Jun Zhai, San Jose, CA (US)

(21) Appl. No.: 14/317,799

(22) Filed: Jun. 27, 2014

(51) Int. Cl. H01L 25/18; H01L 21/56; H01L 25/00

(52) U.S. Cl. CPC H01L 25/18; H01L 25/50; H01L 21/56

(57) ABSTRACT

A semiconductor device package includes a logic die coupled to a memory die in a face-to-face configuration with small interconnect pitch (at most about 50 μm) and small distances between the die (at most about 50 μm). The logic die may be connected to a redistribution layer with terminals that are fanned out, or spaced out, to provide space for the face-to-face connections to the memory die. The memory die may be connected to the logic die before or after the logic die is connected to the redistribution layer. The logic die and the memory die may be at least partially encapsulated in an encapsulant. Routing in the redistribution layer may connect the logic die and/or the memory die to ball grid array terminals coupled to the bottom of the redistribution layer and/or discrete devices coupled to the redistribution layer.

### BACKGROUND

1. Technical Field

Embodiments described herein relate to semiconductor packaging and methods for packaging semiconductor devices. More particularly, some embodiments described herein relate to a package with a memory die interconnected to a logic die in a face-to-face configuration.

2. Description of Related Art

There continues to be a significant push in the semiconductor industry for semiconductor packages to have lower cost, higher performance, increased integrated circuit density, and increased package density. Logic die (e.g., system on a chip (“SoC”)) continue to become more highly integrated, which requires increased interconnection density. Thus, interconnect pitch is being reduced further and further to very fine or ultra fine levels.

Memory die are also continually being placed closer and closer to the logic die to increase bandwidth between the die. The increasing demand of memory bandwidth presents selected challenges to the signal integrity of memory channels within semiconductor packages. As an example, a 12.6 Gps memory bandwidth may require 64 bits (2 channels) memory buses clocking at 800 MHz of DDR (double data rate). Often, two or more memory die are stacked to increase memory capacity in a package.

A typical configuration for putting two (or more) memory die in a package is to vertically stack the memory die (e.g., stack one memory die directly on top of another memory die). Vertically stacking the memory die reduces the overall thickness of the package. Stacking the die vertically, however, creates problems with connecting both die to terminals on the package. Typically, I/Os on the die are connected to the terminals using wire bonding between the top of the memory die (with at least part of the bottom memory die in the stack protruding beyond the edge of the top memory die) and terminals on the substrate of the package.

Using wire bonding, however, increases the height of the package as the wire bond paths are spaced to prevent shorting of the different wire bonds from each memory die. In addition, wire bonding may include wire loops that result in large loop inductance in the 3D domain. The large loop inductance may cause voltage noise due to L di/dt and/or poor signal integrity. Using wire bonding may also limit the number of I/Os available and power delivery to the die.

Through silicon vias (TSVs) from the memory die to the terminals in the package have been used as a solution to overcome some of the problems with wire bonding. Providing TSVs, however, requires special memory die, adds several additional process steps, and is relatively expensive. Flip chip packaging has been widely used for advanced SoC integrated circuits. Flip chip packaging may provide shorter (smaller) impedance and allow more I/O connections and power/ground pins.

### SUMMARY

In certain embodiments, a semiconductor device package includes a logic die coupled to a memory die in a face-to-face configuration with the distance between the die being at most about 50 μm. Terminals that connect the die may have a small interconnect pitch (e.g., at most about 50 μm) that is less than the interconnect pitch of terminals or connections coupling the logic die to a redistribution layer. The terminals or connections coupling the logic die to the redistribution layer may be fanned out, or spaced out, to provide space for the connections to the memory die.

In some embodiments, the memory die is connected to the logic die before encapsulation of the logic die and before the logic die is connected to the redistribution layer in a wafer level process. In some embodiments, the memory die is connected to the logic die after the logic die is encapsulated and after the logic die is connected to the redistribution layer in a wafer level process. In certain embodiments, the redistribution layer couples the logic die and/or the memory die (through the connections to the logic die) to terminals on a lower surface of the redistribution layer (e.g., a ball grid array) through routing in the redistribution layer. The redistribution layer may also couple the logic die and/or the memory die to discrete devices coupled to the redistribution layer through the routing in the redistribution layer.

### BRIEF DESCRIPTION OF THE DRAWINGS

Features and advantages of the methods and apparatus described herein will be more fully appreciated by reference to the following detailed description of presently preferred but nonetheless illustrative embodiments when taken in conjunction with the accompanying drawings in which:

FIG. 1 depicts a cross-sectional representation of a logic die coupled to a carrier.

FIG. 2 depicts a cross-sectional representation of a memory die coupled to a logic die on a carrier.

FIG. 3 depicts a cross-sectional representation of a logic die and a memory die at least partially encapsulated in an encapsulant.

FIG. 4 depicts a cross-sectional representation of a logic die, and a memory die, in an encapsulant coupled to a redistribution layer (RDL) using terminals.

FIG. 5 depicts a cross-sectional representation of semiconductor a device package that includes a logic die, a memory die, and an RDL.

FIG. 6 depicts a cross-sectional representation of a logic die at least partially encapsulated in an encapsulant and coupled to a carrier.

FIG. 7 depicts a cross-sectional representation of a logic die at least partially encapsulated in an encapsulant and coupled to an RDL.

FIG. 8 depicts a cross-sectional representation of a memory die coupled to terminals on an RDL.

FIG. 9 depicts a cross-sectional representation of terminals coupled to an RDL to form a package.

FIG. 10 depicts a cross-sectional representation of a plurality of logic die on a wafer level carrier.

FIG. 11 depicts a cross-sectional representation of an embodiment of a plurality of packages formed on a wafer level RDL.

While the described embodiments are susceptible to various modifications and alternative forms, specific embodiments thereof are shown by way of example in the drawings and will herein be described in detail. The drawings may not be to scale. It should be understood that the drawings and detailed description thereto are not intended to limit the embodiments to the particular form disclosed, but to the contrary, the intention is to cover all modifications, equivalents and alternatives falling within the spirit and scope defined by the appended claims.

### DETAILED DESCRIPTION OF EMBODIMENTS

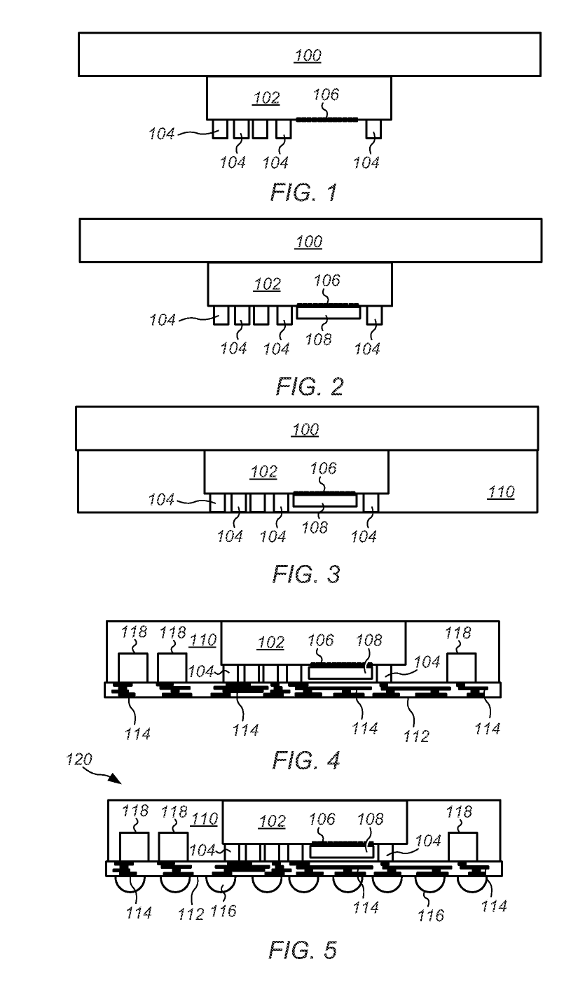

FIGS. 1-5 depict cross-sectional representations of an embodiment of a process flow for forming a semiconductor device package. FIG. 1 depicts a cross-sectional representation of logic die 102 coupled to carrier 100. Carrier 100 may be any carrier suitable for supporting and carrying a thin substrate. Carrier 100 may be, for example, a temporary substrate for a thin substrate made of silicon, glass, or steel. Logic die 102 may be, for example, a system on a chip (“SoC”). In some embodiments, logic die 102 is a flip chip logic die.

In certain embodiments, terminals 104 are coupled to the lower surface of logic die 102. Terminals 104 may include copper, aluminum, or another suitable conductive material. In some embodiments, terminals 104 are solder-coated or Sn-coated. In certain embodiments, terminals 104 are C4 bumps. Terminals 104 may include fan out connections for logic die 102 and power delivery connections for the logic die.

In certain embodiments, terminals 104 are fanned out or spaced out to allow space for terminals 106 to be coupled to logic die 102. Terminals 106 may include copper, aluminum, or another suitable conductive material. Terminals 106 may include connections for coupling logic die 102 to a memory die.

FIG. 2 depicts a cross-sectional representation of memory die 108 coupled to logic die 102 on carrier 100. In certain embodiments, memory die 108 is a DDR (double data rate) die (e.g., an 8 GB DDR die). In some embodiments, memory die 108 is a flip chip memory die. In some embodiments, memory die 108 is a discrete memory die. In some embodiments, memory die 108 includes two or more memory die (e.g., vertically stacked memory die). Although memory die 108 is specifically shown in FIG. 2, other integrated circuit (IC) dies may also be similarly coupled to logic die 102 on carrier 100.

Memory die 108 may be coupled to logic die 102 using terminals 106. In certain embodiments, memory die 108 is coupled to logic die 102 (e.g., the lower surface of the logic die) in a face-to-face configuration. For example, memory die 108 and logic die 102 may be coupled using a flip chip bonding process as both the memory die and the logic die may be flip chip dies.

In certain embodiments, terminals 106 have an interconnect pitch that is at most about 50 μm. In some embodiments, terminals 106 have an interconnect pitch that is between about 30 μm and about 50 μm. In certain embodiments, terminals 106 have a smaller interconnect pitch than terminals 104. The small interconnect pitch of terminals 106 allows a high interconnection density between logic die 102 and memory die 108.

Terminals 106 may also provide a small distance of connection between memory die 108 and logic die 102. In certain embodiments, the upper surface of memory die 108 is at most about 50 μm from the lower surface of logic die 102. In some embodiments, the upper surface of memory die 108 is between about 10 μm and about 50 μm from the lower surface of logic die 102.

After memory die 108 is coupled to logic die 102, the logic die and the memory die (as well as terminals 104 and terminals 106) may be at least partially encapsulated in encapsulant 110, as shown in FIG. 3. Encapsulant 110 may be, for example, a polymer or a mold compound such as an overmold or exposed mold. In some embodiments, encapsulant 110 is overmolded over logic die 102, memory die 108, and terminals 104, 106 and the encapsulant is subsequently grinded down or otherwise polished to expose at least a portion of terminals 104.

After encapsulation, carrier 100 is removed from logic die 102 and encapsulant 110 and the logic die is coupled to a redistribution layer using terminals 104 (e.g., the logic die, memory die 108, terminals 104, and terminals 106 are transferred to the redistribution layer). FIG. 4 depicts a cross-sectional representation of logic die 102, and memory die 108, in encapsulant 110 coupled to redistribution layer (RDL) 112 using terminals 104. Terminals 104 may connect logic die 102 to routing 114 in RDL 112. Routing 114 may connect logic die 102 to other components and/or other terminals coupled to RDL 112.

RDL 112 may include materials such as, but not limited to, PI (polyimide), PBO (polybenzoxazole), BCB (benzocyclobutene), and WPRs (wafer photo resists such as novolak resins and poly(hydroxystyrene) (PHS) available commercially under the trade name WPR including WPR-1020, WPR-1050, and WPR-1201 (WPR is a registered trademark of JSR Corporation, Tokyo, Japan)). RDL 112 may be formed using techniques known in the art (e.g., techniques used for polymer deposition).

RDL 112 may include one or more layers of routing 114. In certain embodiments, RDL 112 includes two or more layers of routing 114. For example, RDL 112 may include between two and five layers of routing 114. Routing 114 may be, for example, copper wiring or another suitable electrical conductor wiring. A thickness of RDL 112 may depend on the number of layers of routing 114 in the RDL. For example, each layer of routing 114 may be between about 5 μm and about 10 μm in thickness. Thus, typically RDL 112 may have a thickness of at least about 5 μm and at most about 50 μm.

After coupling logic die 102 to RDL 112, additional terminals may be coupled to a lower surface of the RDL to form a semiconductor device package. FIG. 5 depicts a cross-sectional representation of semiconductor device package 120 that includes logic die 102, memory die 108, and RDL 112. Terminals 116 are coupled to the lower surface of RDL 112. Terminals 116 may include aluminum, copper, or another suitable conductive material. In some embodiments, terminals 116 are solder-coated or Sn-coated. In certain embodiments, terminals 116 form a ball grid array.

In some embodiments, package 120 includes one or more discrete devices 118 coupled to RDL 112. Discrete devices 118 may be added to package 120 and coupled to RDL 112 at any point in the process flow shown in FIGS. 1-5 using techniques known in the art, Discrete devices 118 may be passive devices such as, but not limited to, resistors, capacitors, inductors, transformers, filters, and couplers. Discrete devices 118 may be coupled to RDL 112 Routing 114 may connect logic device 102 (through terminals 104) and/or memory device 108 (through the logic device and terminals 106) to terminals 116 and/or discrete devices 118. In some embodiments, terminals 116 are used to couple package 120 to a motherboard, a system printed circuit board (PCB), or another package.

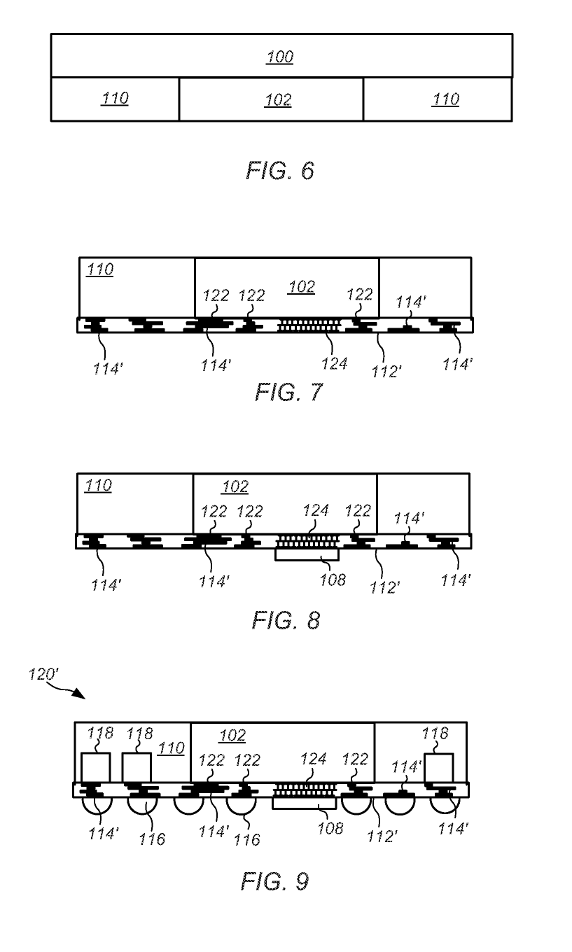

FIGS. 6-9 depict cross-sectional representations of an alternative embodiment of a process flow for forming a semiconductor device package. FIG. 6 depicts a cross-sectional representation of logic die 102 at least partially encapsulated in encapsulant 110 and coupled to carrier 100. Following encapsulation, carrier 100 is removed from logic die 102 and encapsulant 110 and the logic die and encapsulant is coupled to RDL 112′ (e.g., the logic die and the encapsulant are transferred to the redistribution layer), as shown in FIG. 7. In certain embodiments, RDL 112′ includes two or more layers of routing 114′. In some embodiments, RDL 112′ has a thickness between about 10 μm and about 50 μm.

Logic die 102 may be coupled to routing 114′ in RDL 112′ using connections 122. Connections 122 may include landing pads or other terminals that couple logic die 102 to routing 114′ in RDL 112′. For example, connections 122 may include aluminum or copper landing pads or solder-coated or Sn-coated landing pads for coupling routing 114′ to logic die 102.

In certain embodiments, as shown in FIG. 7, RDL 112′ includes terminals 124. Terminals 124 may be, for example, copper or another suitable electrical conductor. In certain embodiments, terminals 122 are one or more layers of routing that passes through RDL 112′ (e.g., the terminals are routing that vertically, or near vertically, directly connects the lower surface of the RDL with the upper surface of the RDL). In some embodiments, terminals 124 are vias through RDL 112′ that are filled with copper or another electrical conductor. For example, vias (such as through-mold vias (TMVs)) may be formed through RDL 112′ and then copper may be plated (or otherwise filled) in the vias to form terminals 124.

In certain embodiments, terminals 124 have an interconnect pitch that is at most about 50 μm. In some embodiments, terminals 124 have an interconnect pitch that is between about 30 μm and about 50 μm. In certain embodiments, terminals 124 have a smaller interconnect pitch than connections 122.

FIG. 8 depicts a cross-sectional representation of memory die 108 coupled to terminals 124 on RDL 112′. Coupling memory die 108 to terminals 124 connects the memory die to logic die 102. Using terminals 124 to connect memory die 108 and logic die 102 directly and vertically, or near vertically, connects the die through RDL 112′. In certain embodiments, memory die 108 is in a face-to-face configuration with logic die 102. For example, memory die 108 may be coupled to terminals 124 on RDL 112′ using a flip chip bonding process that places the memory die and logic die 102 in the face-to-face configuration.

FIG. 9 depicts a cross-sectional representation of terminals 116 coupled to RDL 112′ to form package 120′. While FIGS. 8 and 9 depict terminals 116 being coupled to RDL 112′ after memory die 108 is coupled to terminals 124, it is to be understood that these steps may be reversed with terminals 116 being coupled to the RDL prior to the memory die being coupled to terminals 124. The order of the steps may be dependent on a desired process flow and/or other factors that may affect desirability in the order of steps. Similarly, it may be possible to form terminals 124 in RDL 112′ after terminals 116 are coupled to the RDL and before coupling memory die 108 to terminals 124.

Similar to the embodiment of package 120 depicted in FIG. 5, package 120′, shown in FIG. 9, may include one or more discrete devices 118 coupled to RDL 112′. Discrete devices 118 may be added to package 20′ and coupled to RDL 112′ at any point in the process flow shown in FIGS. 6-9 using techniques known in the art.

Using terminals 106, shown in FIG. 5, or terminals 124, shown in FIG. 9, to connect logic die 102 and memory die 108 in a face-to-face configuration provides a low cost, high bandwidth memory to logic (e.g., SoC) interconnection. For example, using terminals 106 or terminals 124 to connect logic die 102 and memory die 108 in the face-to-face configuration provides small path lengths (e.g., less than about 50 μm) between the die with high interconnect density (e.g., interconnect pitch of at most about 50 μm). The small path length and high interconnect density provides high bandwidth and low latency connection between logic die 102 and memory die 108.

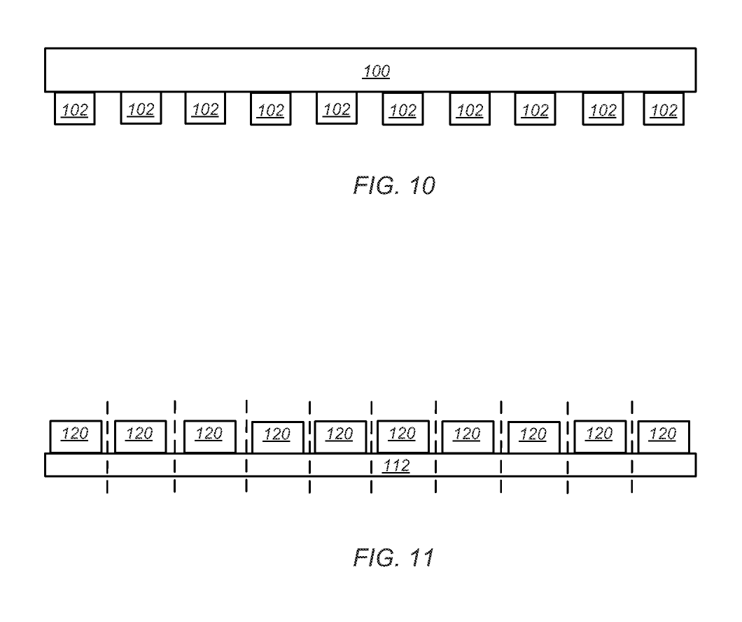

In certain embodiments, a plurality of packages 120 or 120′ are formed simultaneously in a wafer level process. For example, carrier 100, shown in FIGS. 1-3, and 6, may be a wafer level carrier on which a plurality of logic die 102 are coupled, as shown in FIG. 10. The plurality of logic die 102 on carrier 100 may be subject to subsequent processing according to the process flow in FIGS. 1-5 or the process flow in FIGS. 6-9 to form a plurality of packages 120 or packages 120′, respectively, on a wafer level redistribution layer (e.g., RDL 112 or RDL 112′ may be a wafer level redistribution layer). FIG. 11 depicts a cross-sectional representation of an embodiment of a plurality of packages 120 (or 120′) formed on wafer level RDL 112 (or RDL 112′). After forming packages 120 on RDL 112, the packages may be singulated (e.g., separated by dicing or cutting as shown by the dotted lines in FIG. 11) to form individual packages in their final format.

In certain embodiments, package 120 and/or package 120′ described herein is a discrete semiconductor device package. In some embodiments, package 120 and/or package 120′ is used as a top or a bottom package in a PoP (“package-on-package”) package. When used in the PoP package, package 120 and/or package 120′ may include additional connections and/or terminals for use in the PoP package. For example, package 120 and/or package 120′ may include one or more vias (e.g., through-mold vias (TMVs)) through encapsulant 110.

Further modifications and alternative embodiments will be apparent to those skilled in the art in view of this description. Accordingly, this description is to be construed as illustrative only and is for the purpose of teaching those skilled in the art the general manner of carrying out the described embodiments. It is to be understood that the forms of the embodiments shown and described herein are to be taken as the presently preferred embodiments. Elements and materials may be substituted for those illustrated and described herein, parts and processes may be reversed, and certain features may be utilized independently, all as would be apparent to one skilled in the art after having the benefit of this description. Changes may be made in the elements described herein without departing from the spirit and scope as described in the following claims.

1. A semiconductor device package, comprising:
a logic die at least partially encapsulated in an encapsulant;
a memory die coupled to a lower surface of the logic die in a face-to-face configuration;
a redistribution layer coupled to the lower surface of the logic die; and
a plurality of terminals coupled to a lower surface of the redistribution layer, wherein at least some of the terminals are connected to the logic die through routing in the redistribution layer.

2. The package of claim 1, further comprising additional terminals that couple the memory die to the logic die, wherein the additional terminals have a smaller interconnect pitch than the terminals coupled to the redistribution layer.

3. The package of claim 1, wherein the memory die is coupled to the logic die with a plurality of terminals having an interconnect pitch of at most about 50 μm.

4. The package of claim 1, wherein a top surface of the memory die is at most about 50 μm from the lower surface of the logic die.

5. The package of claim 1, further comprising a plurality of additional terminals coupling the lower surface of the logic die to the redistribution layer, wherein the additional terminals are spaced out to allow the memory die to be coupled to the lower surface of the logic die.

6. The package of claim 1, wherein the lower surface of the logic die is directly attached to the redistribution layer.

7. The package of claim 1, wherein the redistribution layer comprises a polymer with two or more layers of routing.

8. The package of claim 1, wherein the memory die is at least partially encapsulated in the encapsulant.

9. The package of claim 1, wherein the terminals coupled to the lower surface of the redistribution layer comprise a ball grid array.

10-20. (canceled)

21. A semiconductor device package, comprising:
a redistribution layer;
a logic die coupled to an upper surface of the redistribution layer using one or more first terminals;
a memory die coupled to a lower surface of the logic die in a face-to-face configuration using one or more second terminals, wherein the memory die is positioned between the logic die and the redistribution layer;
a plurality of third terminals coupled to a lower surface of the redistribution layer, wherein at least some of the third terminals are connected to the logic die through routing in the redistribution layer and at least some of the first terminals; and
an encapsulant formed on the upper surface of the redistribution layer, wherein the encapsulant at least partially encapsulates the logic die and the memory die.

22. The package of claim 21, further comprising one or more passive devices coupled to the upper surface of the redistribution layer on a periphery of the logic die.

23. The package of claim 22, wherein at least one of the passive devices is coupled to the logic device through routing in the redistribution layer and at least one of the first terminals.

24. The package of claim 21, wherein the memory die is coupled to at least some of the third terminals through routing in the redistribution layer, at least one of the first terminals, the logic die, and at least one of the second terminals.

25. The package of claim 21, wherein the second terminals have a smaller interconnect pitch than the first terminals.

26. The package of claim 21, wherein the second terminals have an interconnect pitch of at most about 50 μm.

27. The package of claim 21, wherein a top surface of the memory die is at most about 50 μm from the lower surface of the logic die.

28. The package of claim 21, wherein the first terminals are spaced out to allow the memory die to be coupled to the lower surface of the logic die.
